(19) United States
(12) Patent Application Publication
(10) Pub. No.: US 2026/0085891 A1
(43) Pub. Date: Mar. 26, 2026

(54) OXYGEN CONCENTRATION DETECTION SYSTEM AND REFLOW OVEN USING THE SAME

(71) Applicant: Illinois Tool Works Inc., Glenview, IL (US)

(72) Inventor: Yuexin CHEN, Suzhou New District (CN)

(21) Appl. No.: 19/112,369

(22) PCT Filed: Oct. 26, 2023
(86) PCT No.: PCT/US2023/077913

§ 371 Date: Mar. 17, 2025

(30) Foreign Application Priority Data
Nov. 3, 2022 (CN) 202211368906.X

(51) Int. Cl. F27B 9/40; B23K 1/008; F27B 9/02; F27B 9/30; F27D 19/00; G01N 1/22; H05K 3/34

(52) U.S. Cl. CPC F27B 9/40; B23K 1/008; F27B 9/3005; F27D 19/00; G01N 1/2205; H05K 3/3494; F27B 9/028; F27D 2019/0012; G01N 2001/2282

(57) ABSTRACT

The present application discloses an oxygen concentration detection system for detecting the oxygen concentration in a furnace chamber of a reflow oven, comprising: a cooling device, a filter device, and a detection device. The oxygen concentration detection system of the present application utilizes a semiconductor cooler to condense sample gas within the furnace chamber, thereby removing most of the VOC contaminants in the sample gas. Subsequently, by employing activated carbon adsorption filtration, all contaminants in the gas are basically eliminated, resulting in a more accurate detection result from the detection device. Furthermore, due to the rapid cooling capabilities of the semiconductor cooler and the relatively short sample gas flow distance, the oxygen concentration detection system of the present application is also capable of reducing the required detection time, enabling more timely detection from the detection device. Therefore, the oxygen concentration detection system of the present application is capable of timely and accurately detecting the oxygen concentration in a gas within a reflow oven furnace chamber and adjusting the oxygen content therein according to the detection result, thereby enhancing the soldering quality.

### RELATED APPLICATIONS

This international application claims priority to Chinese Patent Application No. 202211368906.X, filed Nov. 3, 2022. The entirety of Chinese Patent Application No. 202211368906.X is incorporated herein by reference.

### TECHNICAL FIELD

The present application relates to an oxygen concentration detection system for a reflow oven and a reflow oven using the oxygen concentration detection system.

### BACKGROUND

In the production of printed circuit boards, electronic elements are typically mounted to circuit boards using a process called “reflow soldering.” In a typical reflow soldering process, a solder paste (e.g., tin paste) is deposited into a selected area on a circuit board and a wire of one or more electronic components is inserted into the deposited solder paste. The circuit board then passes through a reflow oven in which the solder paste reflows (i.e., is heated to a melting or reflowing temperature) in a heating area and then cools in a cooling zone to electrically and mechanically connect the wires of the electronic components to the circuit board. As used herein, the term “circuit board” comprises a substrate assembly of any type of electronic element, such as comprises a wafer substrate.

In some reflow ovens, air or a substantially inert gas (e.g. nitrogen) is used as a working gas, which is filled in a furnace chamber of a reflow oven. The circuit board to be soldered is conveyed through the furnace chamber via a conveying device, where soldering takes place within the working gas. For a reflow oven that uses a substantially inert gas as the working gas, it is typically necessary to maintain the oxygen concentration in the working gas within a specific range in the furnace chamber for circuit boards with different requirements.

### SUMMARY

One of the objectives of the present application is to provide an oxygen concentration detection system that is capable of timely and accurately detecting the oxygen concentration in a gas within a reflow oven furnace chamber and adjusting the oxygen content therein according to the detection result, thereby enhancing the soldering quality.

The present application provides, in a first aspect, an oxygen concentration detection system for detecting the oxygen concentration in a furnace chamber of a reflow oven. The oxygen concentration detection system comprises a cooling device, comprising a semiconductor cooler, that is configured to receive a sample gas from a furnace chamber and cool the received sample gas through the semiconductor cooler; a filter device, which is fluidly connected to the cooling device, that is configured to carry out contaminant filtering on the gas cooled by the cooling device; and a detection device, which is fluidly connected to the filter device, that is configured to detect the oxygen concentration in the gas from the filter device.

According to the above first aspect, the cooling device further comprises a gas conveying component consisting of a thermally conductive housing and a gas conveying channel positioned within the thermally conductive housing, wherein the gas conveying component is configured to convey a sample gas received from the furnace chamber through the gas channel; wherein the thermally conductive housing comprises a contact surface that is in contact with a semiconductor cooler for heat exchange to cool the sample gas conveyed within the gas conveying channel.

According to the above first aspect, the gas conveying channel has a curved shape.

According to the above first aspect, the gas conveying component further comprises a thermally conductive baffle positioned within the thermally conductive housing. Both the thermally conductive baffle and the thermally conductive housing collectively define the gas conveying channel, wherein the curved surface of the thermally conductive baffle defines the curved shape thereof.

According to the above first aspect, the thermally conductive baffle comprises a first thermally conductive baffle and a second thermally conductive baffle, both of which have a first curved surface and second curved surface that are opposing to each other that, together, define the curved shape of the gas conveying channel.

According to the above first aspect, the thermally conductive housing comprises a base and an upper cover, wherein the base contains an accommodating cavity and the upper cover is being disposed over the base to enclose the accommodating cavity; the thermally conductive baffle is attached to the bottom of the upper cover and extends into the accommodating cavity.

According to the above first aspect, the thermally conductive housing is connected to the top of a semiconductor cooler by a fastener to maintain contact between a contact surface of the thermally conductive housing and the semiconductor cooler.

According to the above first aspect, the contact surface is planar and is formed by the bottom surface of the thermally conductive housing.

According to the above first aspect, the semiconductor cooler comprises a semiconductor cooling plate, a thermally conductive plate, and a heat sink. The semiconductor cooling plate has a relatively disposed heating bottom surface and cooling top surface; the heat sink is disposed beneath and in contact with the heating bottom surface; and the thermally conductive plate is disposed above and in contact with the cooling top surface; wherein, the thermally conductive housing is connected above the thermally conductive plate, with the contact surface being in contact with the surface of the thermally conductive plate.

According to the above first aspect, the temperature of the cooling top surface is 10° C. to 10° C.

According to the above first aspect, the filter device is configured to carry out contaminant filtering by adsorption using activated carbon.

According to the above first aspect, the filter device includes a cartridge defining a cavity, as well as an inlet barrier and an outlet barrier disposed at two opposing axial ends of the cartridge, wherein the cavity is used for housing the activated carbon, and both the inlet and outlet barriers are equipped with several gas openings to enable gas to enter and exit the cartridge while ensuring the activated carbon remains therein.

According to the above first aspect, the filter device further comprises a front end and a rear end respectively disposed at two opposing axial ends of the cartridge, with the front end and the rear end being detachably connected to the cartridge to secure the inlet and outlet barriers at the respective opposing axial ends thereof. Both the rear end and the front end are equipped with an adsorption gas inlet and an adsorption gas outlet, both of which are fluidly connected to the cavity.

According to the above first aspect, both the inlet barrier and the outlet barrier are perforated plates.

According to the above first aspect, the size of the activated carbon is 40-60 mesh.

According to the above first aspect, the detection device is an aspirating oxygen concentration meter that is configured such that the gas flow rate through which is 150-600 mL/min.

According to the above first aspect, when the detection device is configured such that the gas flow rate through which is 150 mL/min, the gas conveyed within the gas conveying channel is cooled from 260-280° C. to 20° C.-40° C.

A second aspect of the present application provides a reflow oven comprising a furnace chamber, in which contains a gas; according to the oxygen concentration detection system described in any one of the first aspects, the oxygen concentration detection system receives a sample gas from the furnace chamber through a cooling device and detects the oxygen concentration in the received sample gas to obtain an oxygen concentration signal; a nitrogen input device, controllably and fluidly connected to the furnace chamber, that is configured to controllably input nitrogen into the furnace chamber; and a control device, that is configured to control the amount of nitrogen input into the furnace chamber by the nitrogen input device according to the real-time oxygen concentration signal.

According to the above second aspect, the reflow oven further comprises a control valve through which the nitrogen input device is controllably and fluidly connected to the furnace chamber; wherein, a control device is communicatively connected to both the oxygen concentration detection system and the control valve.

According to the above second aspect, the oxygen concentration detection system is configured to continuously receive sample gas from the furnace chamber, enabling real-time adjustment of the amount of nitrogen input into the furnace chamber.

The furnace chamber of the reflow oven includes a preheating zone, a peak zone, and a cooling zone; of which, the oxygen concentration detection system is fluidly connected to the peak zone of the furnace chamber to receive the sample gas therefrom.

Other objects and advantages of the present application will be apparent from the description of the present application hereinafter with reference to the accompanying drawings, and may help with a full understanding of the present application.

### BRIEF DESCRIPTION OF THE DRAWINGS

FIG. 1 is a schematic diagram of a reflow oven in accordance with an example of the present application;

FIG. 2 is a perspective view of an oxygen concentration detection system of FIG. 1;

FIG. 3A is a perspective view of a cooling device of FIG. 2A;

FIG. 3B is an exploded view of the cooling device of FIG. 3A from an angle;

FIG. 3C is an exploded view of the cooling device of FIG. 3A from another angle;

FIG. 3D is a cross-sectional view of the cooling device of FIG. 3A along line A-A;

FIG. 4A is a perspective view of a filter device of FIG. 2;

FIG. 4B is an exploded view of the filter device of FIG. 4A from an angle;

FIG. 4C is a schematic diagram of an inlet barrier of FIG. 4A;

FIG. 4D is a cross-sectional view of the filter device of FIG. 4A along line B-B;

FIG. 5 is a perspective view of a detection device of FIG. 2;

FIG. 6 is a schematic diagram of a control device of FIG. 1.

### DETAILED DESCRIPTION

Various specific embodiments of the present application will be described below with reference to the attached drawings that form a part of the present specification. It should be understood that while terms denoting orientation, such as “front,” “rear,” “upper,” “lower,” “left,” “right,” “top,” “bottom,” “inside,” “outside,” “front side,” “rear side” etc., are used in the present application to describe various exemplary structural parts and elements of the present application, these terms are used herein for convenience of illustration only and are determined based on the exemplary orientations shown in the attached drawings. Since the examples disclosed in the present application may be disposed in different orientations, these terms denoting orientation are for illustrative purposes only and should not be considered as limiting.

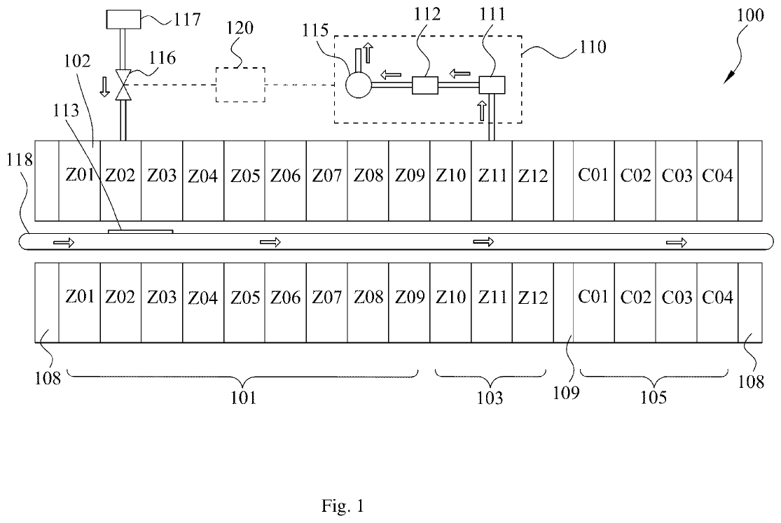

FIG. 1 is a simplified schematic diagram of an example of a reflow oven 100 according to an example of the present application, which is an example of the reflow oven of the present application. As shown in FIG. 1, the reflow oven 100 includes a furnace chamber 102, in which consists of a preheating zone 101, a peak zone 103, and a cooling zone 105 sequentially disposed along the length of the furnace chamber 102 and fluidly connected thereto. The reflow oven 100 further comprises a conveying device 118 that spans the length of the furnace chamber 102 and is used to pass a circuit board 113 to be processed through the furnace chamber 102 from the left end and sequentially through the preheating zone 101, peak zone 103, and cooling zone 105, after which the processed circuit board is output from the right end of furnace chamber 102. When soldering certain circuit boards, a reflow oven requires a substantially inert gas (such as nitrogen) as the working gas. The following explanation will be based on primarily using nitrogen as the working gas.

A heating device is provided in the preheating zone 101 and peak zone 103, respectively (not shown in the figures). In the example shown in FIG. 1, the preheating zone 101 consists of nine sub-preheating zones Z01-Z09, and the peak zone 103 consists of three sub-peak zones Z10-Z12. The sub-preheating zones Z01-Z09 and sub-peak zones Z10 Z12 are connected in succession, with gradual temperature increase. “Connected in succession” means that these sub-zones are arranged sequentially in order of numbering, e.g., sub-peak zone Z10 is located between sub-preheating zone Z09 and sub-peak zone Z11. In the preheating zone 101, the circuit board 113 to be processed is heated and a portion of the flux in the solder paste dispensed on the circuit board 113 vaporizes. Since the temperature of the peak zone 103 is higher than that of the preheating zone 101, the solder paste will melt completely in the peak zone 103. The peak zone 103 is also a region where higher temperature VOCs (e.g., pine sap and resin in the flux) will vaporize.

A cooling device is provided in the cooling zone 105 (not shown in the figures). In the example as shown in FIG. 1, the cooling zone 105 consists of four sub-cooling zones C01-C04, which are arranged sequentially in order of numbering, with gradual temperature decrease. After the circuit board 113 is transported from the peak zone 103 into the cooling zone 105, the fully melted solder paste is cooled and solidified on the soldering area of the circuit board 113, thereby connecting the electronic component to the circuit board 113. Notably, the number of sub-zones in preheating zone 101, peak zone 103, and cooling zone 105 of the reflow oven may vary depending on the product to be welded and different welding processes, not limited to the example shown in FIG. 1.

A barrier exhaust zone 109 is disposed in the connecting region between the sub-peak zone Z12 of peak zone 103 and the sub-cooling zone C01 of cooling zone 105. The barrier exhaust zone 109 may draw or exhaust gas from the furnace chamber 102, thereby hindering or reducing the flow of gas containing volatile contaminants from the peak zone 103 to the cooling zone 105. Moreover, by drawing or exhausting gas from the furnace chamber 102, the barrier exhaust zone 109 may also serve as an insulation zone that separates the high-temperature peak zone 103 from the low-temperature cooling zone 105. In the present example, the reflow oven 100 is also equipped with an exhaust device (not shown in the figures) for discharging gas containing volatile contaminants from the furnace chamber 102. The exhaust device is usually connected to an area of higher temperature in the reflow oven 100, such as the peak zone 103 or the barrier exhaust zone 109.

The reflow oven 100 of the present application uses a working gas primarily composed of nitrogen, as well as oxygen, the content of which is controlled within a specific range. The reflow oven 100 further comprises a gas barrier zone 108 located at a left end and a right end of the furnace chamber 102, respectively. The gas barrier zone 108 is used to supply nitrogen to the furnace chamber 102, forming a nitrogen curtain, which is intended to prevent the entry of ambient air from the external environment into the furnace chamber 102. When the reflow oven 100 is in the operational mode of processing a circuit board, the exhaust device will also remain in an operational mode to maintain the cleanliness of the gas within the furnace chamber 102. During this process, it is also necessary to continuously input clean nitrogen and/or air into the furnace chamber 102 to maintain the required working atmosphere within the furnace chamber 102.

The reflow oven 100 also includes an oxygen concentration detection system 110, a control device 120, and a nitrogen input device 117. The oxygen concentration detection system 110 is used to detect the oxygen concentration in the furnace chamber 102, and the nitrogen input device 117 is used to input nitrogen into the furnace chamber 102. The control device 120 controls the amount of nitrogen input into the furnace chamber 102 by the nitrogen input device 117 according to the oxygen concentration in the furnace chamber 102 detected by the oxygen concentration detection system 110, so as to achieve the oxygen concentration required for a specific soldering process in the reflow oven. In the present example, the oxygen concentration detection system 110 continuously receives the sample gas from the furnace chamber 102, detects the oxygen concentration in the sample gas, and dynamically adjusts the amount of nitrogen input into the furnace chamber 102 by the nitrogen input device 117 according to the real-time detected oxygen concentration.

As previously mentioned, in the reflow oven 100, when the circuit board 113 is conveyed to the preheating zone 101 and the peak zone 103, the VOCs in the solder paste on the circuit board 113 will vaporize to form vapors, which generate contaminants. Contaminants may damage the oxygen concentration detection system 110 or affect the accuracy of the detection result. Accordingly, the oxygen concentration detection system 110 is unable to directly detect the oxygen concentration in the gas within the furnace chamber 102, but requires purification to remove contaminants before detection of oxygen concentration in the gas within the furnace chamber 102 may be carried out.

Specifically, the oxygen concentration detection system 110 consists of a cooling device 111, a filter device 112, and a detection device 115 fluidly connected to one another. The cooling device 111 is fluidly connected to the furnace chamber 102 to receive sample gas therefrom and to cool the received sample gas. When the sample gas is cooled, contaminants therein are re-condensed as liquids or solids, thereby enabling their removal from the sample gas.

The filter device 112 is fluidly connected to the cooling device 111 to carry out impurity filtration on the sample gas that has been cooled by the cooling device 111. After the sample gas undergoes filtration, the contaminants therein are further removed, resulting in a sample gas that is substantially free from contaminants.

The detection device 115 is fluidly connected to the filter device 112 to detect oxygen concentration in the sample gas coming from the filter device 112. The sample gas is discharged from the reflow oven 100 after the detection process. In some examples, the detection device 115 is fluidly connected to an exhaust device, allowing the sample gas to be discharged from the reflow oven 100 through the exhaust device after the detection process.

In the present example, the cooling device 111 is fluidly connected to the higher-temperature peak zone 103 of the furnace chamber 102, such as being fluidly connected to the sub-peak zone Z11, to receive sample gas from sub-peak zone Z11. In the reflow oven 100, the peak zone 103 has the highest temperature and is a critical area affecting soldering quality during the soldering process. For example, the gas temperature in the sub-peak zone Z11 typically ranges from 260-280° C. In the examples of the present application, by detecting the oxygen concentration in the peak zone 103 and adjusting the nitrogen supply according to the detected oxygen concentration therein, it is possible to maintain the oxygen concentration in the peak zone 103 at the set value required for the soldering process, thereby significantly enhancing the soldering quality. Additionally, the peak zone 103 is an area where VOCs in the solder paste vaporize and produce contaminants. The present application is capable of improving the accuracy of the detection device 115 in detecting oxygen concentration by first condensing the sample gas through the cooling device 111 and filtering the gas through the filter device 112 thereafter to obtain a sample gas with very low contaminant content, which enters the detection device 115 for oxygen concentration detection.

In the present example, the nitrogen input device 117 is fluidly connected to a lower-temperature area of the furnace chamber 102 through a control valve 116, such as being fluidly connected to the preheating zone 101, to input nitrogen into the furnace chamber 102. As a more specific example, the supply of nitrogen to the furnace chamber 102 from the nitrogen input device 117 positioned near to an inlet of the furnace chamber 102, specifically the sub-preheating zone Z02, allows ambient nitrogen from the nitrogen input device 117 to enter into a lower-temperature zone, thereby avoiding a significant impact on gas temperature in a higher-temperature zone. Those skilled in the art would understand that the nitrogen input device 117 is also capable of supplying nitrogen to the furnace chamber 102 from a location proximate to an outlet, that is sub-cooling zone Z03, through a control valve, or supplying nitrogen to the furnace chamber 102 from both the sub-preheating zone Z02 and sub-cooling zone Z03 simultaneously through a control valve, both of which are within the protective scope of the present application.

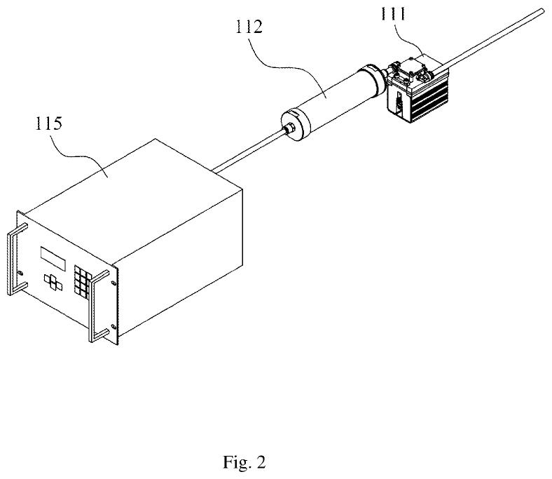

FIG. 2 is a perspective view of the oxygen concentration detection system 110 of FIG. 1. As shown in FIG. 2, the cooling device 111, the filter device 112, and the detection device 115 are sequentially and fluidly connected through a duct. In the present example, the detection device 115 is an aspirating oxygen concentration meter which, through aspiration, enables sample gas discharged from the furnace chamber 102 to sequentially pass through the cooling device 111, the filter device 112, and the detection device 115. As one example, the detection device 115 enables gas to pass through at a flow rate of 150-600 mL/min. In other words, sample gas drawn from the furnace chamber 102 flows through the oxygen concentration detection system 110 at a rate of 150-600 mL/min. Those skilled in the art would understand that in some other examples, the flow direction and flow rate of a gas may also be controlled by the installation of a fan in a duct.

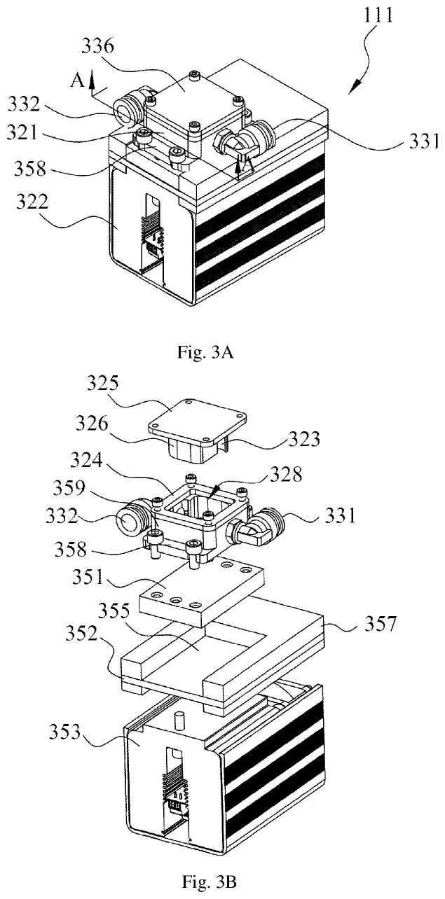

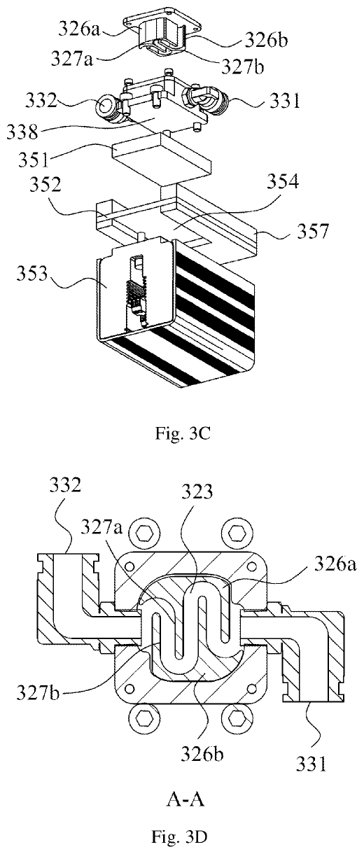

FIGS. 3A-3D show the specific structures of the cooling device 111, wherein FIG. 3A is a perspective view of the cooling device 111, FIG. 3B is an exploded view of the cooling device 111 from one angle, FIG. 3C is an exploded view of the cooling device 111 from another angle, and FIG. 3D is a cross-sectional view of the cooling device 111 along line A-A. As shown in FIGS. 3A-3D , the cooling device 111 consists of a semiconductor cooler 322 and a gas conveying component 336, wherein the gas conveying component 336 conveys sample gas discharged from the furnace chamber 102 through a duct to the filter device 112, and the semiconductor cooler 322 provides the cooling capacity necessary to cool the sample gas within the gas conveying component 336.

As shown in FIGS. 3A-3D , the gas conveying component 336 comprises a thermally conductive housing 321 and a gas conveying channel 323 positioned within the thermally conductive housing 321, which is connected to the top of the semiconductor cooler 322 and secured thereto by means of a fastener such as a bolt. The semiconductor cooler 322 cools the sample gas in the gas conveying channel 323 through contact-based heat exchange with the thermally conductive housing 321. The thermally conductive housing 321 is made of a thermally conductive material, such as a thermally conductive metal like aluminum alloy. In the present example, the thermally conductive housing 321 comprises a base 324, which includes a square box body portion 359 with an accommodating cavity 328 that is used to form the gas conveying channel 323. The bottom surface of the base 324 forms a contact surface 338, which is in contact with the semiconductor cooler 322. As one specific example, the bottom of the thermally conductive housing 321 protrudes outward of the box body portion 359 to form a flange 358, which is flush with the bottom surface of the box body portion 359 to collectively create a planar contact surface 338. The disposal of the flange 358 enables the fastener to connect the thermally conductive housing 321 to the semiconductor cooler 322 in one aspect, while increasing the contact surface area between the contact surface 338 and the semiconductor cooler 322 in the other.

The thermally conductive housing 321 further comprises an upper cover 325 that is disposed over the box body portion 359 of the base 324 by a fastener (such as a bolt) and encloses the accommodating cavity 328 within the base 324. In the present example, the bottom of the upper cover 325 is connected to a thermally conductive baffle 326. The thermally conductive baffle 326 is made of a thermally conductive material, such as a thermally conductive metal like aluminum alloy. When the upper cover 325 is disposed over the box body portion 359 of the base 324, the thermally conductive baffle 326 extends from the lower surface of the upper cover 325 into the accommodating cavity 328 to the base 324, such that the thermally conductive baffle 326 and the thermally conductive housing 321 collectively define the gas conveying channel 323. With further reference to FIG. 3D, in the present example, the gas conveying channel 323 is configured in an elongated, curved shape, such as a serpentine shape, to extend the flow distance of the sample gas for thorough cooling. Specifically, the thermally conductive baffle 326 includes a first thermally conductive baffle 326a and a second thermally conductive baffle 326b that are being spaced apart in the longitudinal direction of the semiconductor cooler 322. The first thermally conductive baffle 326a has a first curved surface 327a disposed on the inner side thereof. The second thermally conductive baffle 326b has a second curved surface 327b disposed on the inner side thereof. Additionally, the first curved surface 327a and the second curved surface 327b are relatively disposed to form a serpentine-shaped gas conveying channel 323 between them.

Those skilled in the art would understand that the length of the gas conveying channel 323, which corresponds to the flow distance of the sample gas, needs to be set within a reasonable range. When the length of the gas conveying channel 323 is too long, the sample gas may be more thoroughly cooled, but it also results in a longer flow time for the sample gas, leading to a delay in the detection of oxygen concentration in the furnace chamber 102 by the detection device 115. When the length of the gas conveying channel 323 is too short, the sample gas may not be sufficiently cooled.

The thermally conductive housing 321 is also connected to an inlet duct 331 and an outlet duct 332, wherein the inlet duct 331 is fluidly connected to the furnace chamber 102 through a connecting duct, and the outlet duct 332 is fluidly connected to the filter device 112 through a connecting duct. Moreover, the inlet duct 331 and the outlet duct 332 are fluidly connected to both ends of the gas conveying channel 323. As a result, after being discharged from the furnace chamber 102, the sample gas is able to enter the gas conveying channel 323 through the inlet duct 331 and be cooled within the gas conveying channel 323. This cooling process condenses most of the contaminants in the sample gas, leaving them in the gas conveying channel 323 and enabling the remaining sample gas to be discharged from the outlet duct 332 into the filter device 112.

Those skilled in the art would understand that regular cleaning of the gas conveying component 336 is necessary due to the presence of residual contaminants in the gas conveying channel 323 after condensation. The separable base 324 and upper cover 325 are designed to facilitate the cleaning of the gas conveying channel 323, allowing for the removal of any residual condensate therein. In some examples, the base 324 and upper cover 325 of the thermally conductive housing 321 may also be integrally formed.

The semiconductor cooler 322 consists of a semiconductor cooling plate 352, a thermally conductive plate 351, and a heat sink 353. The semiconductor cooling plate 352 is a flat plate made of a semiconductor material. When the semiconductor cooling plate 352 is operational, the top surface forms a cooling top surface 355 used for cooling, and the bottom surface forms a heating bottom surface 354 used for heating. The thermally conductive plate 351 is disposed over and in contact with the cooling top surface 355 to transfer the cooling capacity of the latter. The heat sink 353 is disposed beneath and in contact with the heating bottom surface 354 to transfer the heat generated by the latter. In the present example, the semiconductor cooler 322 further comprises a mounting gasket 357 to which the semiconductor cooling plate 352 is mounted. The thermally conductive plate 351, mounting gasket 357, and heat sink 353 are fixedly connected by means of adhesive bonding or fasteners.

The thermally conductive plate 351 is rectangular in shape and made of a thermally conductive material, the bottom surface of which is in contact with the cooling top surface 355 of the semiconductor cooling plate 352, and the top surface of which is in contact with the contact surface 338 of the thermally conductive housing 321. As such, the thermally conductive plate 351 is capable of facilitating the transfer of cooling capacity provided by the semiconductor cooling plate 352 to the thermally conductive housing 321, which is then used to cool the sample gas in the gas conveying channel 323. The thermally conductive plate 351 serves the dual purpose of transferring cooling capacity and facilitating the secure attachment of thermally conductive housing 321 by a fastener. In the present example, the semiconductor cooling plate 352 is in contact with the thermally conductive plate 351, which is also in contact with the thermally conductive housing 321. By using an appropriate thermally conductive material, the surface contact heat transfer method is capable of realizing a high level of heat transfer efficiency. The heat sink 353 is square in shape and made of a thermally conductive material, the top surface of which is in contact with the heating bottom surface 354 of the semiconductor cooling plate 352 to dissipate the heat provided by the semiconductor cooling plate 352 to the external environment.

As such, the semiconductor cooling plate 352 is capable of cooling the sample gas in the gas conveying channel 323 through the thermally conductive plate 351 and thermally conductive housing 321, thereby effectively condensing and removing most of the contaminants in the sample gas.

The semiconductor cooling plate 352 possesses the advantages of rapid cooling and a low cooling temperature. However, the total cooling capacity is limited. After being powered on, [the semiconductor cooling plate 352] is capable of rapidly reducing its temperature to low levels, making it particularly suitable for rapidly lowering the temperature of the sample gas, especially when the flow rate is not high. For instance, when the semiconductor cooling plate 352 is operational, the temperature of the cooling top surface 355 may reach-10° C. to 10° C., thus being capable of cooling the sample gas that is being conveyed within the gas conveying channel 323 at a flow rate of 150 mL/min from 260-280° C. to 20° C.-40° C. Therefore, the sample gas extracted from the furnace chamber is able to rapidly condense to enable the removal of most of the contaminants and then undergo adsorption filtration for further purification.

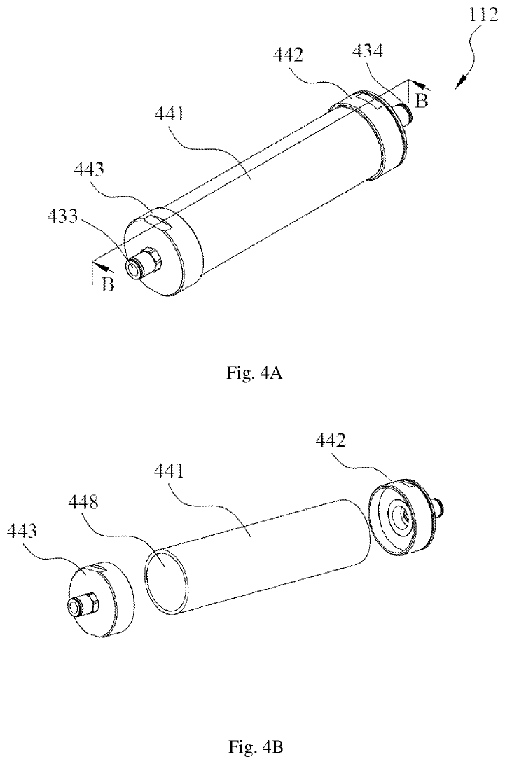

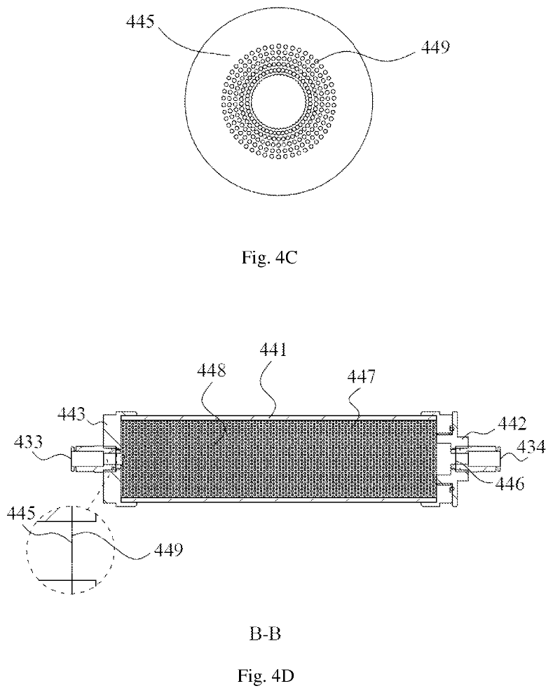

FIGS. 4A-4D show the specific structures of the filter device 112, wherein FIG. 4A is a perspective view of the filter device 112, FIG. 4B is an exploded view of the filter device 112, FIG. 4C is a top view of the inlet barrier 445 of filter device 112, and FIG. 4D is a cross-sectional view of the filter device 112 along line B-B. As shown in FIGS. 4A-4D, the filter device 112 includes a cartridge 441 defining a cavity 448, as well as a front end 443 and a rear end 442 relatively disposed at two opposing axial ends of the cartridge 441. The front end 443 and the rear end 442 enclose the two ends of the cavity 448 along the axial direction of the cartridge 441. The front end 443 is provided with an adsorbent gas outlet 433, which is fluidly connected to the detection device 115 via a connecting duct. The rear end 442 is provided with an adsorbent gas inlet 434, which is fluidly connected to the cooling device 111 via a connecting duct. In the samples of the present application, the front end 443 and the rear end 442 are detachably connected to both ends of the cartridge 441 by such means as adhesive bonding or snap-fitting, enabling the replacement of the adsorbent material contained within the cavity 448 of cartridge 441.

The cavity 448 is designed to house adsorbent materials such as activated carbon 447. This setup allows sample gas discharged from the cooling device 111 to enter the adsorbent gas inlet 434 into the cavity 448, where contaminant filtering takes place by adsorption on the activated carbon 447 as the gas passes through the filter device 112 for further purification, before flowing out from the adsorbent gas outlet 433 to the detection device 115. The size of activated carbon 447 may be set to an appropriate size. When the size of activated carbon 447 is too large, the gaps between the particles thereof will be increased, leading to an increased gas volume in the cavity 448 and thereby prolonging the flow time of the sample gas. This may result in a delay in the detection of oxygen concentration in the furnace chamber 102 by detection device 115. Conversely, when the size of activated carbon 447 is too small, it may be easily drawn into detection device 115. As one specific example, the size of activated carbon 447 in the cavity 448 is 40-60 mesh.

The filter device 112 also comprises an inlet barrier 445 and an outlet barrier 446, both of which are relatively disposed at two opposing axial ends of the cartridge 441 and held in place within the rear end 442 and the front end 443, respectively. Both the inlet barrier 445 and outlet barrier 446 are equipped with several gas openings 449 to enable sample gas to enter and exit the cartridge 441, while ensuring the activated carbon inside cavity 448 remains within cartridge 441. In this example, both the inlet barrier 445 and outlet barrier 446 are perforated plates, the size of gas openings 449 is configured to be less than the size of activated carbon 447, this way gas may pass through gas openings 449, but activated carbon 447 may not past through gas openings 449. In some other examples, both the inlet and outlet barriers may also be such components as filter cotton that allow gas to pass through while preventing activated carbon from passing through.

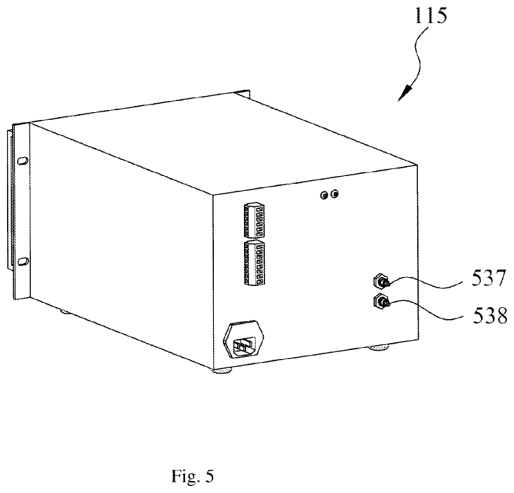

FIG. 5 shows the specific structure of the detection device 115. As shown in FIG. 5, the detection device 115 is an aspirating oxygen concentration meter equipped with a detection gas inlet 537 and a detection gas outlet 538. A clean sample gas discharged from the filter device 112 enters the detection device 115 from the detection gas inlet 537 and is then discharged to the external environment or centrally discharged through the detection gas outlet 538 after the oxygen concentration therein has been detected.

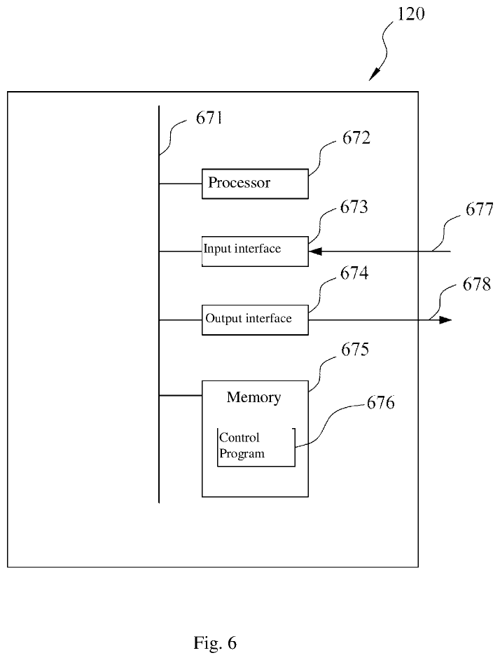

FIG. 6 is a simplified schematic diagram of an example of a control device 120 in FIG. 1. The control device 120 comprises a bus 671, a processor 672, an input interface 673, an output interface 674, and a memory 675 with a control program 676. The processor 672, the input interface 673, the output interface 674 and the memory 675 are communicatively connected through the bus 671, such that the processor 672 is capable of controlling the operation of the input interface 673, the output interface 674 and the memory 675. The memory 675 is used to store programs, instructions, and data, while the processor 672 reads programs, instructions, and data from the memory 675 and is capable of writing data to the memory 675.

The input interface 673 receives signals and data via the connection 677, such as an oxygen concentration signal from the oxygen concentration detection system 110, along with various parameters for manual input, and so on. The output interface 674 sends signals and data via the connection 678, such as a control signal to the control valve 116 to adjust the opening. The memory 675 stores data such as the control program 676 and preset values for the predetermined oxygen concentration. Various parameters may be preset in the manufacturing process, or may be set by manual input or data import during use. The processor 672 obtains various signals, data, programs, and instructions from the input interface 673 and the memory 675, processes them accordingly, and outputs them through the output interface 674. For example, when the oxygen concentration detection system 110 detects an oxygen concentration above a preset value, the amount of nitrogen delivered by the nitrogen input device 117 into the furnace chamber 102 is increased through the control valve 116. When the oxygen concentration detection system 110 detects an oxygen concentration below a preset value, the amount of nitrogen delivered by the nitrogen input device 117 into the furnace chamber 102 is decreased through the control valve 116.

In a typical reflow oven, the removal of contaminants in a sample gas within a furnace chamber is achieved through condensation by means of air cooling or water cooling, with the temperature of the cooling medium at around 50° C. The process may cool the sample gas within the furnace from 260-280° C. to 100° C. After cooling, the VOC contaminant content in the sample gas is reduced to 70.1 ppm. Using such a condensation method in an oxygen concentration detection system would result in a higher contaminant level in the sample gas, making it challenging to remove the contaminants entirely through subsequent activated carbon adsorption filtration. Moreover, the elevated temperature of the sample gas would adversely affect the adsorption efficiency of the activated carbon.

The oxygen concentration detection system of the present application uses a semiconductor cooler to condense a sample gas in a furnace chamber. This method takes advantage of the semiconductor cooler's ability to rapidly achieve a lower temperature, cooling the sample gas from 260-280° C. to 20-40° C. As a result, the VOC contaminant content in the sample gas is reduced to just 5.6 ppm after the cooling process is complete. Therefore, it is evident that by cooling the sample gas to 20-40° C. using the semiconductor cooler, most of the VOC contaminants in the sample gas may be removed. Subsequently, by employing activated carbon adsorption filtration, all contaminants in the gas are basically eliminated, resulting in a more accurate detection result from the detection device. Furthermore, due to the rapid cooling capabilities of the semiconductor cooler and the relatively short sample gas flow distance, the oxygen concentration detection system of the present application is also capable of reducing the required detection time, enabling more timely detection from the detection device.

In addition, the oxygen concentration detection system of the present application is able to further reduce the detection time by providing a gas flow channel of an appropriate length and using activated carbon adsorbent material of a suitable size. The detection time of the oxygen concentration detection system of the present application is only 1-2 seconds, and the control device is able to adjust the nitrogen input in real time according to the oxygen concentration detection result, without affecting the closed-loop gas regulation of the reflow oven. Therefore, the oxygen concentration detection system of the present application is capable of timely and accurately detecting the oxygen concentration in a gas within a reflow oven furnace chamber and adjusting the oxygen content therein according to the detection result, thereby enhancing the soldering quality.

Although the present disclosure has been described in conjunction with the examples described above, various alternatives, modifications, variations, improvements, and/or substantial equivalents, whether known or foreseeable now or in the near future, may be apparent to those having at least ordinary skill in the art. In addition, the technical effects and/or technical problems described in the present Specification are exemplary and not limiting; therefore, the disclosure in the present Specification may be used to solve other technical problems and have other technical effects and/or may solve other technical problems. Therefore, the examples of the present disclosure as set forth above are intended to be illustrative and not limiting. Various changes may be made without departing from the spirit or scope of the present disclosure. Therefore, the present disclosure is intended to include all known or earlier developed alternatives, modifications, variations, improvements and/or substantial equivalents.

1. An oxygen concentration detection system for detecting the oxygen concentration in a furnace chamber of a reflow oven, wherein the oxygen concentration detection system comprises:
a cooling device, comprising a semiconductor cooler, that is configured to receive sample gas from the furnace chamber and cool the received sample gas through the semiconductor cooler;
a filter device, which is fluidly connected to the cooling device, that is configured to carry out contaminant filtering on the gas cooled by the cooling device; and
a detection device, which is fluidly connected to the filter device, that is configured to detect oxygen concentration in the gas from the filter device.

2. The oxygen concentration detection system of claim 1, wherein:
the cooling device further comprises a gas conveying component consisting of a thermally conductive housing and a gas conveying channel positioned within the thermally conductive housing, wherein the gas conveying component is configured to convey a sample gas received from the furnace chamber through the gas channel;
wherein the thermally conductive housing comprises a contact surface that is in contact with the semiconductor cooler for heat exchange to cool the sample gas conveyed within the gas conveying channel.

3. The oxygen concentration detection system of claim 2, wherein the gas conveying channel has a curved shape.

4. The oxygen concentration detection system of claim 2, wherein the thermally conductive housing is connected to the top of the semiconductor cooler by a fastener to maintain contact between the contact surface of the thermally conductive housing and the semiconductor cooler.

5. The oxygen concentration detection system of claim 2, wherein the contact surface is planar and is formed by the bottom surface of the thermally conductive housing.

6. The oxygen concentration detection system of claim 2, wherein:
the semiconductor cooler comprises a semiconductor cooling plate, a thermally conductive plate, and a heat sink. The semiconductor cooling plate has a relatively disposed heating bottom surface and cooling top surface; the heat sink is disposed beneath and in contact with the heating bottom surface; and the thermally conductive plate is disposed above and in contact with the cooling top surface; and
wherein, the thermally conductive housing is connected above the thermally conductive plate, with the contact surface being in contact with the surface of the thermally conductive plate.

7. The oxygen concentration detection system of claim 6, wherein the temperature of the cooling top surface is −10° C., to 10° C.

8. The oxygen concentration detection system of claim 1, wherein the filter device is configured to carry out contaminant filtering by adsorption using activated carbon.

9. The oxygen concentration detection system of claim 8, wherein the size of the activated carbon is 40-60 mesh.

10. The oxygen concentration detection system of claim 1, wherein the detection device is an aspirating oxygen concentration meter that is configured such that the gas flow rate through which is 150-600 mL/min.

11. The oxygen concentration detection system of claim 10, wherein when the detection device is configured such that the gas flow rate through which is 150 mL/min, the gas conveyed within the gas conveying channel is cooled from 260-280° C. to 20° C.-40° C.

12. A reflow oven, comprising:
a furnace chamber, containing a gas;
according to the oxygen concentration detection system described in claim 1, the oxygen concentration detection system receives a sample gas from the furnace chamber through a cooling device and detects the oxygen concentration in the received sample gas to obtain an oxygen concentration signal;
a nitrogen input device, controllably and fluidly connected to the furnace chamber, that is configured to controllably input nitrogen into the furnace chamber; and
a control device that is configured to control the amount of nitrogen input into the furnace chamber by the nitrogen input device according to the real-time oxygen concentration signal.

13. The reflow oven according to claim 12, further comprising a control valve through which the nitrogen input device is controllably and fluidly connected to the furnace chamber;
wherein, a control device is communicatively connected to both the oxygen concentration detection system and the control valve.

14. The reflow oven according to claim 12, wherein the oxygen concentration detection system is configured to continuously receive sample gas from the furnace chamber, enabling real-time adjustment of the amount of nitrogen input into the furnace chamber.

15. The reflow oven according to claim 12, wherein the furnace chamber comprises a preheating zone, a peak zone, and a cooling zone;
wherein the oxygen concentration detection system is fluidly connected to the peak zone of the furnace chamber to receive the sample gas therefrom.
